(19) United States
(12) Patent Application Publication
(10) Pub. No.: US 2014/0377965 A1
(43) Pub. Date: Dec. 25, 2014

(54) DIRECTED SELF-ASSEMBLY (DSA) FORMULATIONS USED TO FORM DSA-BASED LITHOGRAPHY FILMS

(71) Applicant: GLOBALFOUNDRIES Inc., Grand Cayman (KY)

(72) Inventors: Gerard M. Schmid, Rensselaer, NY (US); Ji Xu, Watervliet, NY (US); Richard A. Farrell, Albany, NY (US)

(21) Appl. No.: 13/921,520

(22) Filed: Jun. 19, 2013

(51) Int. Cl. H01L 21/02

(52) U.S. Cl. CPC H01L 21/02118; H01L 21/02112; H01L 21/02282; H01L 21/02356
USPC 438/778; 524/562; 524/588; 524/548; 524/104; 524/173; 524/366; 524/230; 524/370; 524/317

(57) ABSTRACT

An illustrative DSA formulation disclosed herein includes a block copolymer material, a casting solvent and at least one plasticizer agent. An illustrative method disclosed herein includes depositing a liquid DSA formulation on a guide layer, performing a spin-coating process to form a DSA-based material layer comprised of the liquid DSA formulation above the guide layer, wherein the DSA-based material layer includes at least one plasticizing agent and, after performing the spin-coating process, performing at least one heating process on the DSA-based material layer while at least some of the plasticizing agent remains in the DSA-based material layer so as to enable phase separation of block copolymer materials.

### BACKGROUND OF THE INVENTION

1. Field of the Invention

Generally, the present disclosure relates to the manufacture of semiconductor devices, and, more specifically, to various Directed Self-Assembly (DSA) formulations used to form DSA-based lithography films, and methods of patterning underlying structures using such DSA-based films.

2. Description of the Related Art

The fabrication of advanced integrated circuits, such as CPUs, storage devices, ASICs (application specific integrated circuits) and the like, requires a large number of circuit elements, such as transistors, capacitors, resistors, etc., to be formed on a given chip area according to a specified circuit layout. During the fabrication of complex integrated circuits using, for instance, MOS (Metal-Oxide-Semiconductor) technology, millions of transistors, e.g., N-channel transistors (NFETs) and/or P-channel transistors (PFETs), are formed on a substrate including a crystalline semiconductor layer. A field effect transistor, irrespective of whether an NFET transistor or a PFET transistor is considered, typically includes doped source and drain regions that are formed in a semiconducting substrate and separated by a channel region. A gate insulation layer is positioned in contact with the channel region and a conductive gate electrode is positioned in contact with the gate insulation layer. By applying an appropriate voltage to the gate electrode, the channel region becomes conductive and current is allowed to flow from the source region to the drain region.

Photolithography is one of the basic processes used in manufacturing integrated circuit products. At a very high level, photolithography involves: (1) forming a layer of light or radiation-sensitive material, such as a photoresist material, above a layer of material or a substrate to be patterned; (2) selectively exposing the radiation-sensitive material to a light generated by a light source (such as a DUV or EUV source) to transfer a pattern defined by a mask or reticle (interchangeable terms as used herein) to the radiation-sensitive material; and (3) developing the exposed layer of radiation-sensitive material to define a patterned mask layer. Various process operations, such as etching or ion implantation processes, may then be performed on the underlying layer of material or substrate through the patterned mask layer.

Of course, the ultimate goal in integrated circuit fabrication is to faithfully reproduce the final circuit layout (design) on the integrated circuit product. Historically, the pitches between features employed in integrated circuit products were large enough such that a desired pattern of such features could be formed using a single patterned photoresist masking layer. However, in recent years, device dimensions and pitches have been reduced in size to the point where existing photolithography tools, e.g., 193 nm wavelength photolithography tools, cannot form a single patterned mask layer with all of the features of the overall target pattern. That is, existing 193 mm wavelength photolithography tools and techniques are generally limited to printing patterns having a pattern pitch above about 70 nm using a single layer of a patterned photoresist material. Accordingly, device designers have resorted to various techniques that involve performing multiple exposures to define a single target pattern in a layer of material or substrate. One such technique is generally referred to as double patterning or double patterning technology (DPT). In general, double patterning is an exposure method that involves splitting (i.e., dividing or separating) a dense overall target circuit pattern into two separate, less-dense patterns. The simplified, less-dense patterns are then printed separately utilizing two separate patterned photoresist masking layers (where one of the patterned masking layers is utilized to image one of the less-dense patterns, and the other patterned masking layer is utilized to image the other less-dense pattern). Further, in some cases, the second pattern is printed in between the lines of the first pattern such that the imaged wafer has, for example, a feature pitch which is half that found on either of the two less-dense patterned masking layers. This technique effectively enables the printing of even smaller features than would otherwise be possible using a single patterned layer of photoresist material using existing photolithography tools. There are several double patterning techniques employed by semiconductor manufacturers.

While such double patterning techniques can enable the printing of features with pitches less than can be formed using a single layer of patterned photoresist material, such double patterning processes are time-consuming and require a great deal of precision in terms of overlay accuracy. So-called sidewall image transfer techniques can also be employed to form patterns having reduced pitches, but such sidewall image transfer techniques are also time-consuming and expensive.

Patterned masking layers have also been formed using various directed self-assembly (DSA) processes in an attempt to produce patterned masking layers that can be employed in forming the very small structures that are required when making modern integrated circuit products. In general, DSA-based lithography layers are formed using self-assembling block copolymers that are positioned above a so-called “guide pattern” and then processed in a variety of different ways so as to enable phase separation of the block copolymer materials. Ultimately, the block copolymer materials arrange themselves in a patterned arrangement of features, e.g., spaced-apart line-type features, spaced-apart cylinder-type features, etc. In forming a layer of line-type features, the DSA process may be controlled such that the width and pitch of such line-type features may be controlled by controlling the composition of the DSA materials. More importantly, using DSA formation techniques, the line width and pitch of the features in a DSA-based patterned masking layer may be formed to substantially smaller dimensions than they could otherwise be formed using traditional photolithography tools and equipment.

In general, forming DSA-based masking layers involves initially forming a guide layer above a substrate or layer of material (structure) so as to guide the phase separation process that occurs in forming DSA-based material layers. After the guide layer is formed, a liquid DSA formulation is spin-coated onto the guide layer so as to form a DSA-based material layer. Prior art DSA formulations include a plurality of block copolymers and a casting solvent that facilitates spin-coating to form a uniform thin film.

In general, there are two prior art techniques that are commonly employed to induce alignment in DSA-based masking layers: (1) so-called thermal annealing DSA techniques and (2) so-called solvent annealing DSA techniques. FIG. 1A graphically depicts the basic process operations performed in forming DSA-based masking layers using a thermal annealing DSA technique. In general, the thermal annealing DSA technique involves performing one or more heating or baking processes on the DSA material layer so as to achieve the desired phase separation. In FIG. 1A, the horizontal axis is the processing time while the vertical axis represents the amount of casting solvent remaining in the DSA material layer. The curve in FIG. 1A generally reflects that the amount of casting solvent in the DSA material layer decreases as various process operations are performed on the DSA material layer. As shown at point “A” in FIG. 1A, the liquid DSA formulation is deposited above the guide layer and the spin-coating process begins at the processing time “I” shown on the horizontal axis. As initially deposited, the liquid DSA formulation is mostly casting solvent, e.g., about 90-99% casting solvent and 1-10% block copolymer material. As shown in FIG. 1A, the spin-coating process is performed from the time period I-III, during which time the concentration of casting solvent in the DSA material layer decreases. During the spin-coating process, at point “B” a substantial amount of casting solvent has evaporated, e.g., only about 5-30% of the casting solvent remains in the DSA material layer and the DSA material layer has now become a stable, vitreous film. The spin-coating process referenced in FIG. 1A is typically performed at ambient temperature, although it may be performed under heated conditions if desired. During the processing time period between points II to III of the spin-coating process, the amount of casting solvent in the now vitreous DSA material layer evaporates at a very low rate and may even remain substantially unchanged. At point III, the spin-coating process is stopped as any further significant evaporation of the remaining casting solvent cannot be achieved by using spin-coating techniques. After the spin-coating process has stopped, one or more heating processes or bakes (beginning at processing time III in FIG. 1A) are performed to vaporize the residual amount of casting solvent in the vitreous DSA material layer. The heating processes or bakes are continued for a sufficiently long period of time such that substantially all of the casting solvent is removed from the vitreous DSA material layer, as reflected in FIG. 1A. Typically, as depicted, most if not substantially all of the residual casting solvent is removed very early during the heating process. In one illustrative embodiment, the thermal annealing process may be a single heating process that is performed at a temperature of about 250° C. for a duration of about five minutes. As noted above, during the heating process, casting solvent is driven from the vitreous DSA material layer and phase separation is induced in the block copolymer material. In general, extended heating of the vitreous DSA material layer at or above the glass transition temperature (Tg) enables the desired phase separation of the block copolymer materials and self-assembly of the separated copolymers with a very low number of defects. Ultimately, one of the components of the separated copolymers is removed to thereby form a patterned DSA-based masking layer that may then be used as described above. Although such thermal annealing is an effective process for processing DSA-based masking layers, the relatively long-duration heating process is a very time-consuming process which translates into undesirable higher costs of production in the highly-competitive business of semiconductor manufacturing.

FIG. 1B graphically depicts the basic process operations performed in forming DSA-based masking layers using a solvent annealing DSA technique. In general, the solvent annealing DSA technique is more complicated and requires more precision as compared to the thermal annealing DSA technique discussed above. In FIG. 1B, as with FIG. 1A, the horizontal axis is the processing time while the vertical axis represents the amount of casting solvent remaining in DSA material layer. In general, the processes involved using a solvent annealing DSA technique and a thermal annealing DSA technique are basically the same up until processing time III in FIG. 1B, i.e., the point where the spin-coating process has been completed and only about 5-30% of the casting solvent remains in the stable, vitreous DSA material layer. In the solvent annealing DSA technique, after the spin-coating process has stopped, an initial relatively lower temperature and relatively shorter duration heating process or bake is performed during the processing time period III-IV to vaporize the residual amount of casting solvent in the vitreous DSA material layer. Typically, as depicted, most if not all of the residual casting solvent is removed very early during this initial heating process. In one illustrative embodiment, the initial heating or baking process may be performed at a temperature of about 150° C. for a duration of about 30-60 seconds. Unlike the thermal annealing DSA technique, at this point in a solvent annealing DSA technique, the vitreous DSA material layer is exposed to a solvent anneal process (processing time period IV-V) in a gaseous processing ambient comprised of a so-called annealing solvent. As depicted in region “D” in FIG. 1B, the annealing solvent is absorbed into the vitreous DSA material layer and it acts to lower the glass transition temperature of the vitreous DSA material layer, i.e., the system plasticizes (increases the fluidity of) the vitreous DSA material layer which thereby enhances the mobility of the polymer chains within the vitreous DSA material layer and induces phase separation in the block copolymer material, as indicated in the region E in FIG. 1B. However, the presence of the annealing solvent within the vitreous DSA material layer alters the thermodynamics of the phase separation process and can alter the size and shape of the equilibrium pattern in the resulting DSA-based material layer. The annealing solvent must be removed after phase separation occurs to stabilize the film, but the removal of the solvent can affect the equilibrium pattern in the DSA material layer. To accomplish the removal of a substantial amount of the annealing solvent, the vitreous DSA material layer is subjected to a so-called “quench” process as indicated between the processing times V-VI and region F on FIG. 1B. The quench process may be a relatively low temperature heating process, e.g., about 150° C. for a duration of about 30-60 seconds, and/or the gaseous annealing solvent may be removed from the ambient of the DSA material layer. However, the quenching process is a very sensitive process operation that requires very fine process control to prevent the formation of an undesirable level of defects in the DSA-based masking layers.

The present disclosure is directed to various Directed Self-Assembly (DSA) formulations used to form DSA-based lithography films that may solve or at least reduce some of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various Directed Self-Assembly (DSA) formulations used to form DSA-based lithography films, and methods of patterning underlying structures using such DSA-based films. One illustrative DSA formulation disclosed herein includes a block copolymer material, a casting solvent and at least one plasticizer agent.

One illustrative method disclosed herein includes depositing a liquid DSA formulation on a guide layer, wherein the liquid DSA formulation includes a block copolymer material, a casting solvent and at least one plasticizing agent, performing a spin-coating process to form a DSA-based material layer comprised of the liquid DSA formulation above the guide layer, wherein the DSA-based material layer includes the at least one plasticizing agent and, after performing the spin-coating process, performing at least one heating process on the DSA-based material layer while at least some of the plasticizing agent remains in the DSA-based material layer so as to enable phase separation of the block copolymer materials into a plurality of first and second separated polymer features positioned above the guide layer.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1B depict various illustrative prior art techniques of forming DSA-based masking layers;

FIGS. 2A-2B are graphic depictions of various illustrative DSA formulations disclosed herein used to form DSA-based material layers; and

FIGS. 3A-3E depict one illustrative method of using DSA-based masking layers disclosed herein for patterning underlying structures.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to various Directed Self-Assembly (DSA) formulations used to form DSA-based masking layers, and methods of patterning underlying structures using such DSA-based masking layers. As will be readily apparent to those skilled in the art upon a complete reading of the present application, the methods disclosed herein are applicable to forming patterned masking layers that may be used in forming integrated circuit products using a variety of technologies, e.g., NFET, PFET, CMOS, etc., and they may be employed when forming a variety of integrated circuit products, including, but not limited to, ASIC's, logic devices, memory devices, etc. With reference to the attached drawings, various illustrative embodiments of the methods disclosed herein will now be described in more detail.

In general, the presently disclosed inventions are broadly directed to forming patterned DSA-based masking layers above a structure. The novel methods disclosed herein will be disclosed in the context of forming a patterned DSA-based masking layer above an illustrative substrate. However, as will be appreciated by those skilled in the art after a complete reading of the present application, the methods disclosed herein may be employed in forming any type of patterned DSA-based masking layer above any type of underlying structure, e.g., a substrate, a layer of gate electrode material that is to be patterned, a layer of insulating material that is to be patterned such that a conductive line/via may be formed therein, a layer of material that is to be subjected to an ion implantation process, etc. Moreover, the patterned DSA-based masking layers disclosed herein may be employed for any processing purpose, e.g., as an etch mask, as an ion implantation mask, etc. Thus, the inventions disclosed herein should not be considered to be limited to the formation of a patterned DSA-based masking layer above any particular type of underlying structure, nor to the ultimate use of such a patterned DSA-based masking layer. To the extent that the structure is a semiconductor substrate, such a substrate may have a variety of configurations, such as a bulk substrate configuration, an SOI (silicon-on-insulator) configuration, and it may be made of materials other than silicon. Thus, the terms “substrate” or “semiconductor substrate” should be understood to cover all semiconducting materials and all forms of such materials.

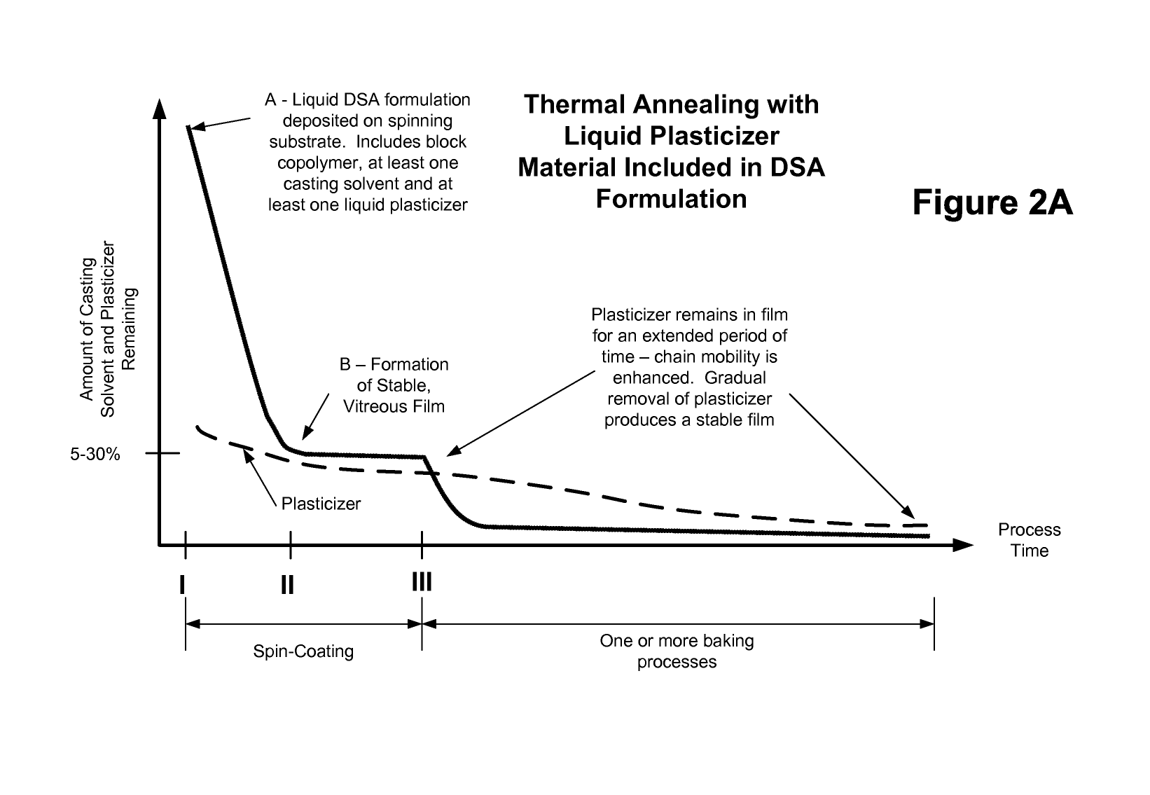

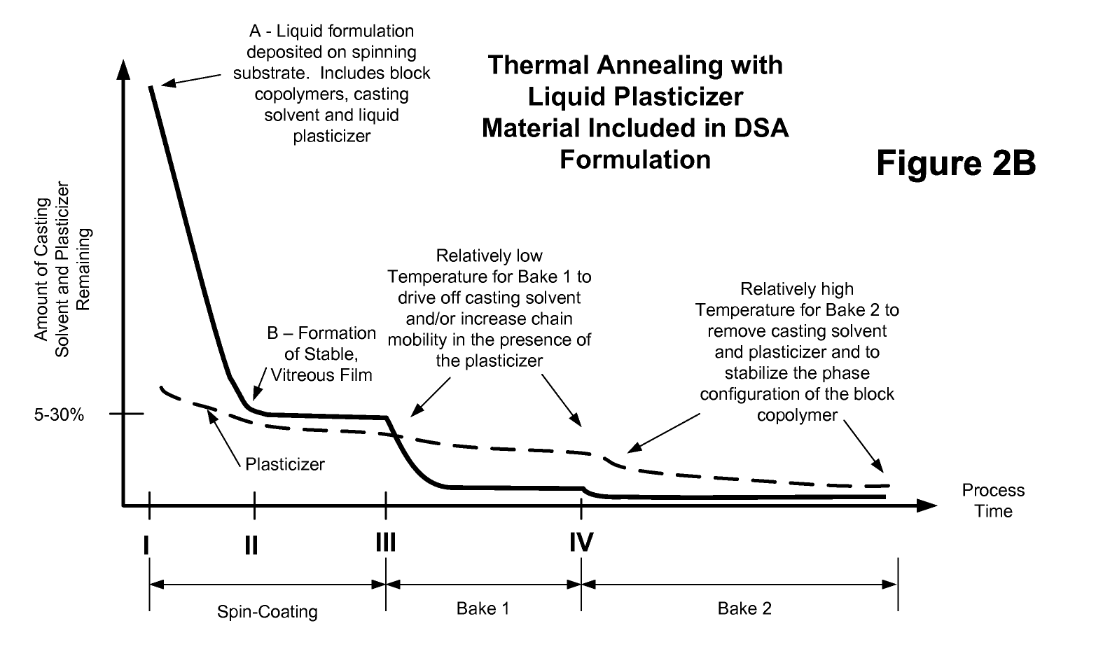

FIGS. 2A-2B are graphic depictions of various illustrative DSA formulations disclosed herein that may be used to form DSA-based material layers. FIG. 2A graphically depicts the basic process operations performed in forming DSA-based material layers in accordance with one illustrative method disclosed herein. In general, the liquid DSA formulations disclosed herein include a quantity of at least one plasticizer agent, a quantity of a block copolymer material and a quantity of one or more casting solvents. In its pure form at room temperature and pressure, the plasticizer agent(s) may be liquid or solid. In another embodiment, the plasticizer agent(s) and the casting solvent are miscible. The liquid DSA formulations disclosed herein, including the plasticizer agent(s), are deposited on the guide layer and the spin-coating process is started, as reflected at point A in FIG. 2A. In FIG. 2A, the horizontal axis is the processing time while the vertical axis represents the amount of casting solvent remaining in DSA material layer as well as the amount of the plasticizer agent(s) remaining in the DSA material layer. The curve in FIG. 2A generally reflects that the amount of casting solvent and the plasticizer agent(s) in the DSA material layer decreases as various process operations are performed on the DSA material layer. The solid curve in FIG. 2A depicts the amount of casting solvent remaining in the DSA material layer as processing proceeds, while the dashed line in FIG. 2A depicts the concentration of just the plasticizer agent(s) remaining in the DSA material layer as processing proceeds. The amount of the plasticizer agent(s) that is contained in the initial liquid DSA formulations disclosed herein may vary depending upon the particular application. In one illustrative embodiment, the liquid DSA formulations disclosed herein may include between 60-90% casting solvent, about 1-10% block copolymers and about 10-40% plasticizer agent(s). In one particular embodiment, the relative amounts of such materials may be about 70% casting solvent, about 2% block copolymers and about 28% plasticizer agent(s). The presently disclosed inventions may be employed with any type of block copolymer material and with any type of casting solvent. In one illustrative embodiment, the liquid DSA formulations disclosed herein may include block copolymer materials such as, for example, poly(styrene-block-methylmethacrylate), poly(styrene-block-dimethylsiloxane), poly(styrene-block-vinylpyridine), etc. The casting solvents that may be employed with the liquid DSA formulations disclosed herein include, but are not limited to, propylene glycol monomethyl ether acetate (PGMEA), propylene glycol monomethyl ether (PGME), toluene, diglyme, etc.

In general, the plasticizer agent(s) is selected based upon a variety of factors. For example, in one embodiment, the plasticizer agent(s) may be selected based upon its capability to remain in the vitreous DSA material layer after substantially all of the casting solvent has been removed from the DSA material layer. Such a characteristic of the plasticizer agent(s) results in increased mobility of the polymer chains during the phase separation process, which enhances production throughput (shorter heating times) and increases the likelihood that fewer defects will be formed in the final patterned DSA-based masking layer. The plasticizer agent(s) may be chosen such that it can enhance polymer chain mobility at ambient temperature and/or at elevated bake temperatures that may be performed when forming the DSA-based material layers. Other factors that may be appropriate to consider when selecting the appropriate plasticizer agent(s) include, but are not limited to, its solubility in one or more of the blocks of the block copolymer material, its boiling point, its vapor pressure versus temperature characteristic, etc. In one illustrative embodiment, the plasticizer agent(s) may be selected from the following group of relatively high-boiling point materials: NMP, DMSO, diglyme, xylene, dimethyl acetamide, dimethyl formamide, biphenyl, bibenzyl, diphenyl ether, etc. In one illustrative embodiment, the plasticizer agent(s) disclosed herein may have a boiling point temperature greater than about 120° C., and, in one particular embodiment, a boiling point temperature that falls within the range of about 120-220° C.

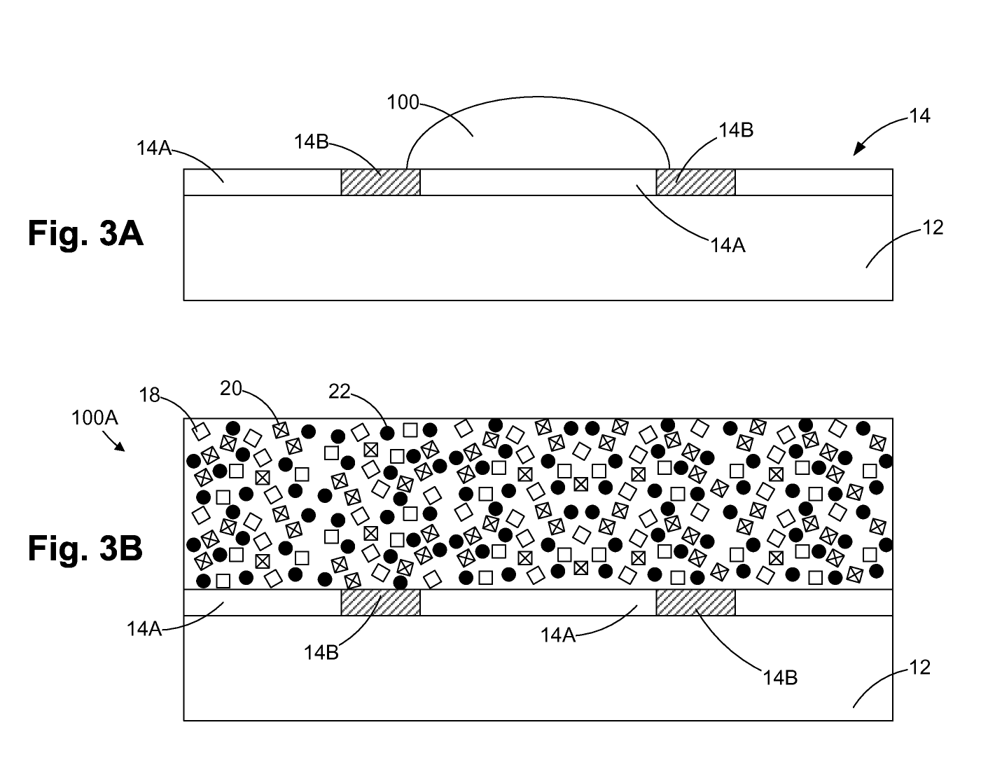

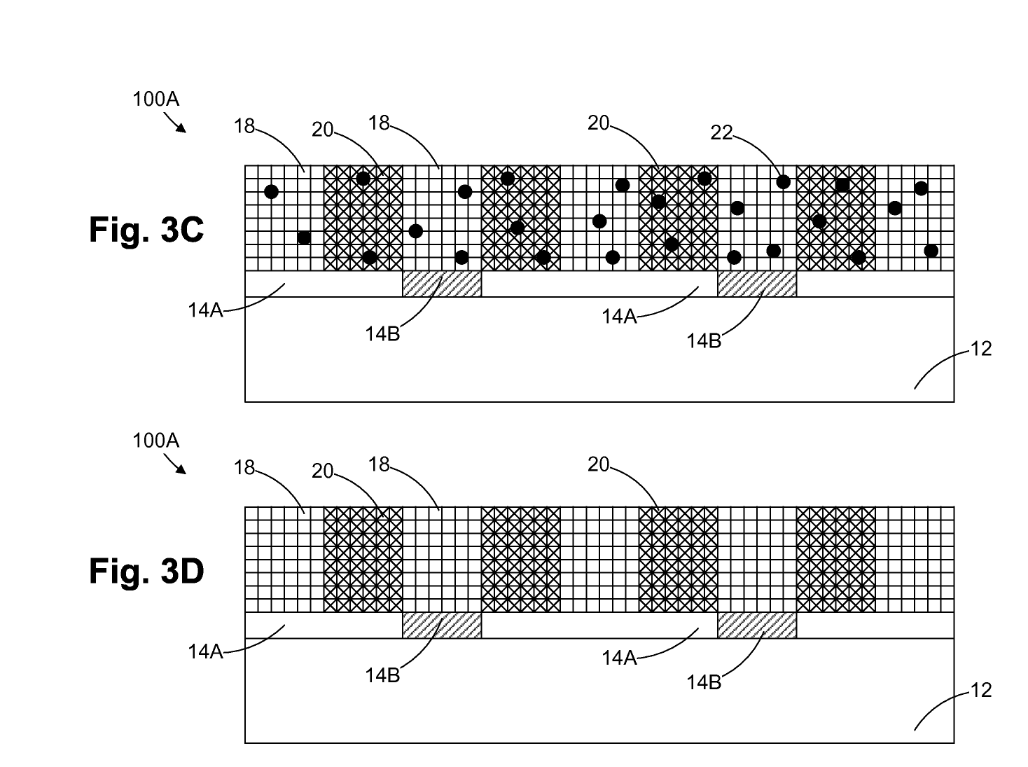

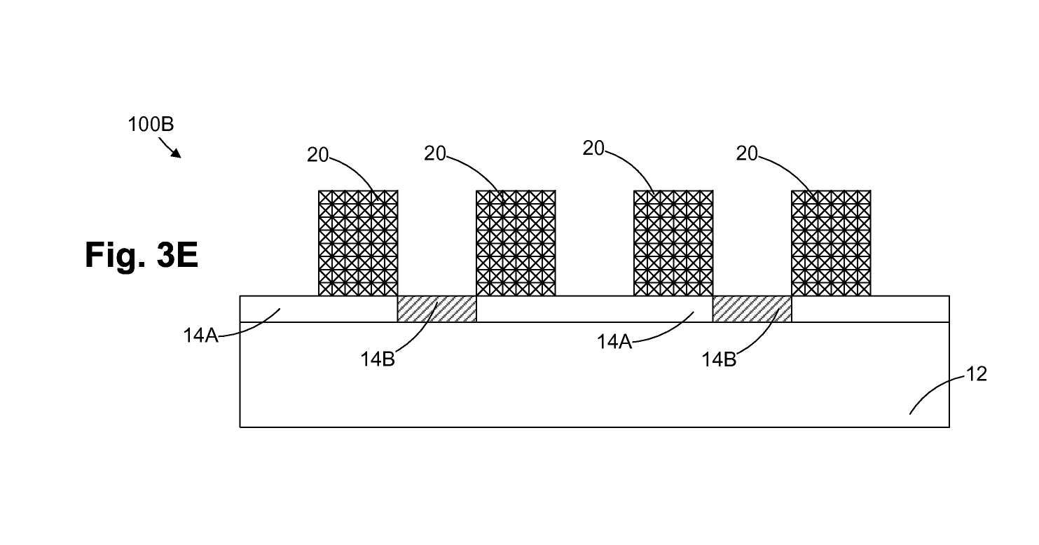

FIGS. 3A-3E depict one illustrative method of using the liquid DSA formulations disclosed herein to form DSA-based masking layers disclosed herein above underlying structures. FIG. 3A depicts an illustrative substrate or structure 12 with an illustrative guide layer 14 formed thereabove. The guide layer 14 is generally comprised of a plurality of neutral regions 14A and a plurality of selective attraction regions 14B. In general, the neutral regions 14A will attract both of the copolymer materials in the liquid DSA formulations disclosed herein, while the selective attraction regions 14B will only attract one of the copolymer materials in the DSA formulations disclosed herein. The materials of construction and the manner in which such guide layers 14 may be formed above the structure 12 are well known to those skilled in the art.

With continuing reference to FIGS. 2A and 3A, the casting solvent is removed at a faster rate than that of the plasticizer agent(s) as the DSA material layer is subjected to various process operations. As shown at point “A” in FIG. 2A and in FIG. 3A, a quantity of the liquid DSA formulations 100 disclosed herein is deposited above the guide layer 14. The quantity, shape and location where the quantity of the liquid DSA formulation 100 is deposited on the guide layer 14 are by way of example only. Typically, the structure 12 is rotating at a high speed (e.g., 500-2500 rpm) at the time the quantity of the liquid DSA formulation 100 is deposited on the guide layer 14 such that the quantity of the liquid DSA formulation 100 spreads out across the guide layer 14 quickly.

FIG. 3B is a simplistic depiction of a DSA-based material layer 100A that may be formed using the DSA formulations 100 disclosed herein. FIG. 3B is intended to simplistically depict such a DSA-based material layer at the point in the process operation where the spin-coating process has just begun and the DSA-based material layer 100A has been initially formed above the guide layer 14. In FIGS. 3B-3E, the block copolymer material has been simplistically depicted as being comprised of a first polymer material 18 (depicted by clear square-shaped features) and a second polymer material 20 (depicted by cross-hatched square-shaped features). The plasticizer agent(s) that is included in the liquid DSA formulations 100 disclosed herein is simplistically depicted as black circles 22. No attempt has been made to depict the casting solvent materials that would be present in the DSA-based material layer 100A. The quantity of the features 18, 20 and 22 in the attached figures are not intended to be representative of the relative amount of such materials that are present in the liquid DSA formulations 100 disclosed herein prior to depositing the liquid DSA formulation 100 on the guide layer 14 or in the resulting DSA-based material layer 100A.

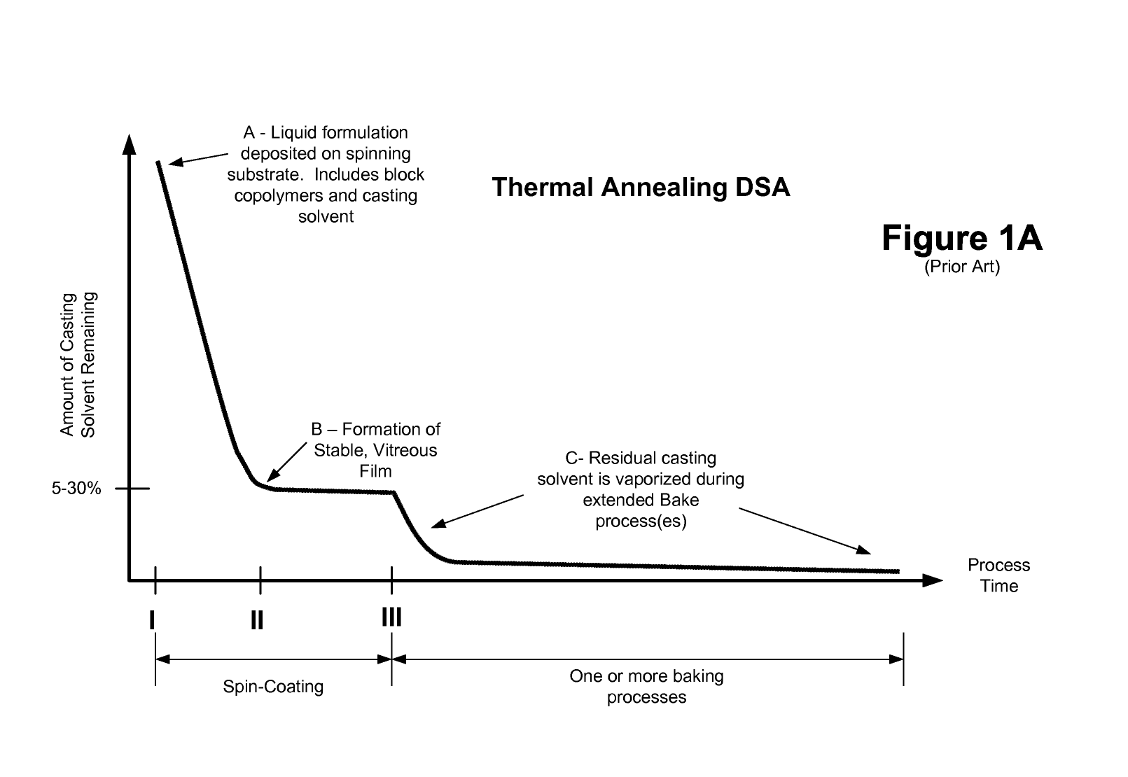

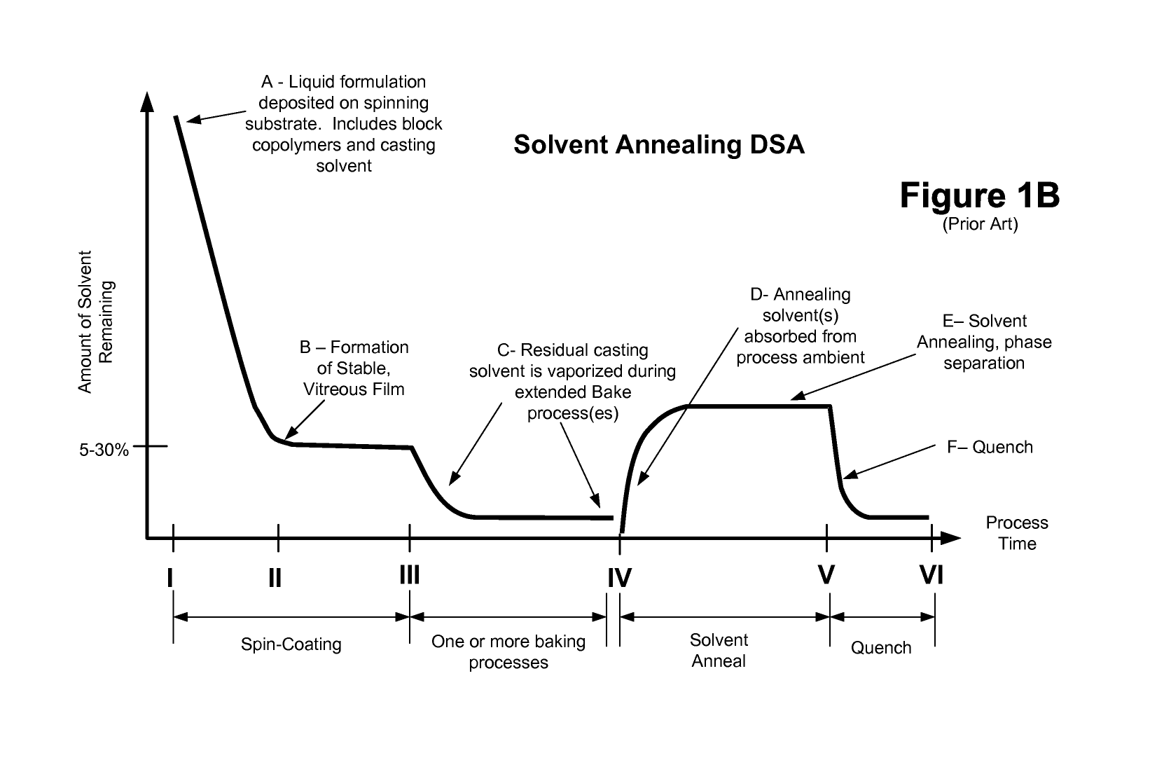

As shown in FIG. 2A, the spin-coating process is performed from the time period I-III, during which time the concentration of casting solvent in the DSA-based material layer 100A decreases at a faster rate than that of the plasticizer agent(s). At processing time II in the spin-coating process (e.g., at point “B”), a substantial amount of casting solvent has evaporated, e.g., only about 5-30% of the casting solvent remains in the DSA-based material layer 100A and the DSA-based material layer 100A has now become a stable, vitreous film that still includes a significant amount of the plasticizer agent(s), e.g., about 2-20% of the mass of the film. The spin-coating process referenced in FIG. 2A is typically performed at ambient temperature, although it may be performed at higher temperatures if desired. During the process time period between points II to III of the spin-coating process, the amount of casting solvent in the now vitreous DSA-based material layer 100A evaporates at a very low rate and may even remain substantially unchanged. Also note that, within the process time period II-III, the amount of the plasticizer agent(s) may be somewhat decreased, although that may not be the case in all applications. At point III, the spin-coating process is stopped. In the embodiment depicted in FIG. 2A, after the spin-coating process has stopped, a single heating process or bake (beginning at process time “III” in FIG. 2A) is performed to vaporize the residual amount of casting solvent in the vitreous DSA-based material layer 100A and to gradually remove the plasticizer agent(s). The heating process or bake is continued for a sufficiently long period of time such that substantially all of the casting solvent is removed from the vitreous DSA-based material layer 100A, as reflected in FIG. 2A. Typically, as depicted, most if not all of the residual casting solvent is removed very early during the heating process. In one illustrative embodiment, the heating process may be performed at a temperature of about 150-200° C. for a duration of about three minutes. Note that this heating process is performed at a lower temperature and for a shorter duration than the corresponding prior art heating process depicted in FIG. 1A. The heating process depicted in FIG. 2A is designed to enable selective desorption of the casting solvent at a rate that is higher than the desorption rate of the plasticizer agent(s). During the heating process shown in FIG. 2A, casting solvent is driven from the vitreous DSA-based material layer 100A and phase separation is induced in the block copolymer material. Note that, due to its lower rate of desorption from the DSA-based material layer 100A, the plasticizer agent(s) remains in the DSA-based material layer 100A for a significant period of time, thereby increasing the chain mobility of the polymer materials during this heating process. Accordingly, the presence of the plasticizer agent(s) allows for a reduction in the duration and temperature of the heating process that is performed to achieve the desired phase separation of the block copolymer material with a very low defect density, as compared to the prior art heating process discussed above in connection with FIG. 1A. At the end of the heating process shown in FIG. 2A, the plasticizer agent(s) may constitute about 0-5% of the mass of the DSA-based material layer 100A.

FIG. 3C simplistically depicts the DSA-based material layer 100A after the heating process depicted in FIG. 2A has been performed and after the desired phase separation of the block copolymer materials 18, 20 in the DSA-based material layer 100A has been achieved. More specifically, the first polymer materials 18 and the second polymer materials 20 have been separated into discreet, ordered features, e.g., line-type features. As depicted, the neutral regions 14A of the guide layer 14 attract both the first polymer materials 18 and the second polymer materials 20, while the selective attraction regions 14B of the guide layer 14 only attract the first polymer materials 18. In the embodiment shown in FIG. 3C, some of the plasticizer agent(s) 22 is distributed within the DSA-based material layer 100A, and may or may not be concentrated within one of the multiple phases 18, 20. FIG. 3D depicts an embodiment where substantially all of the plasticizer agent(s) 22 were removed from the DSA-based material layer 100A as a result of performing the above-described heating processes.

As shown in FIG. 3E, a process operation is performed to selectively remove the first polymer material 18 features from the DSA-based material layer 100A so as to thereby define a patterned DSA-based masking layer 100B comprised of the features defined by the remaining second polymer materials 20. At the point of processing depicted in FIG. 3E, an etching process is performed through the patterned DSA-based masking layer 100B on the underlying guide layer 14 so as to thereby expose the desired portion of the underlying structure 12. Thereafter, various process operations, such as etching or ion implantation processes, may then be performed on the exposed portions of the structure 12 through the patterned DSA-based masking layer 100B. As will be recognized by those skilled in the art after a complete reading of the present application, by use of the liquid DSA formulations 100 disclosed herein (which include the plasticizer(s)) the formation of patterned DSA-based masking layers 100B may be accomplished more quickly, which results in significant cost-savings as compared to the thermal annealing DSA technique discussed in the background section to this application. Additionally, using the liquid DSA formulations 100 disclosed herein, the process of forming high quality patterned DSA-based masking layers 100B is not as process-sensitive as the prior art solvent annealing DSA technique disclosed in the background section of this application, thereby reducing the chances of forming unacceptable levels of defects in the patterned DSA-based masking layer 100B produced herein as compared to the prior art solvent annealing DSA technique. Accordingly, use of the liquid DSA formulations 100 disclosed herein offers significant cost-of-production advantages to a semiconductor manufacturer as compared to the prior art techniques of forming patterned DSA-based masking layers.

FIG. 2B graphically depicts the basic process operations performed in forming DSA-based masking layers using another illustrative method disclosed herein. In general, in this embodiment, multiple heating processes are performed using different temperatures or temperature gradients to optimize the DSA process. For example, in one embodiment, the parameters of a first heating process may be selected so as to maximize the chain mobility within the DSA-based masking layer 100B during the phase separation process, and the parameters of a second heating process may be selected so as to drive off the casting solvent and plasticizer agent(s) so as to stabilize the phase configuration within the DSA-based masking layer 100B. This alternative method involves performing the same processing operations as discussed above during the processing time period I-III, i.e., the spin-coating process. Thus, such discussions will not be again repeated. The solid curve in FIG. 2B depicts the amount of casting solvent remaining in the DSA material layer as processing proceeds, while the dashed line in FIG. 2B depicts the concentration of just the plasticizer agent(s) remaining in the DSA material layer as processing proceeds. As shown in FIG. 2B, the spin-coating process is performed from the time period I-III, during which time the concentration of casting solvent in the DSA-based material layer 100A decreases at a much greater rate than that of the plasticizer agent(s). In the embodiment depicted in FIG. 2B, after the spin-coating process has stopped, a first heating process (Bake 1) is performed during the processing time period III-IV. In one illustrative embodiment, the first heating process may be performed at a temperature of about 150° C. for a duration of about two minutes. Thereafter, a second heating process (Bake 2) is performed beginning at processing time IV through process completion. In one illustrative embodiment, the second heating process may be performed at a temperature of about 200° C. for a duration of about one minute. Note that, in the illustrative example described herein, the first heating process is performed at a relatively lower temperature and for a relatively longer duration as compared to the second heating process. Of course, as noted above, in this embodiment, multiple heating processes are performed using different temperatures or temperature gradients to optimize the DSA process. Thus, the present inventions should not be considered to be limited to the illustrative two-step heating process described in connection with FIG. 2B or the illustrative parameters of such heating processes. For example, if desired, three or more tailored heating processes may be performed to enhance the DSA process. At the end of the multiple heating process shown in FIG. 2B, the plasticizer agent(s) may constitute about 0-5% of the mass of the DSA-based material layer 100A, and the desired phase separation of the block copolymer materials 18, 20 in the DSA-based material layer 100A has been achieved, as shown in FIGS. 3C/3D. Thereafter, as shown in FIG. 3E, a processes operation is performed to selectively remove the first polymer material 18 from the DSA-based material layer 100A so as to thereby define a patterned DSA-based masking layer 100B comprised of the features defined by the remaining second polymer materials 20. As before, at the point of processing depicted in FIG. 3E, various process operations, such as etching or ion implantation processes, may then be performed on the underlying structure 12 through the patterned DSA-based masking layer 100B.

As should be clear from the foregoing, the novel liquid DSA formulations 100 and methods of making and using patterned DSA-based masking layers 100B disclosed herein provide an efficient and effective means of forming patterned DSA-based masking layers that may solve or at least reduce some of the problems identified in the background section of this application. As will be recognized by those skilled in the art after a complete reading of the present application, by use of the liquid DSA formulations 100 disclosed herein (which include the liquid plasticizer(s)), the formation of patterned DSA-based masking layers 100B may be accomplished more quickly, which results in significant cost-savings as compared to the thermal annealing DSA technique discussed in the background section to this application. Additionally, using the liquid DSA formulations 100 disclosed herein, the process of forming high quality patterned DSA-based masking layers 100B is not as process-sensitive as the prior art solvent annealing DSA technique disclosed in the background section of this application, thereby reducing the chances of forming unacceptable levels of defects in the patterned DSA-based masking layer 100B produced herein as compared to the prior art solvent annealing DSA technique. Accordingly, use of the liquid DSA formulations 100 disclosed herein offers significant cost-of-production advantages to a semiconductor manufacturer as compared to the prior art techniques of forming patterned DSA-based masking layers.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

What is claimed:

1. A liquid DSA formulation, comprising:
a block copolymer material;
a casting solvent; and
at least one plasticizer agent.

2. The formulation of claim 1, wherein said at least one plasticizer agent has a boiling point temperature equal to or greater than 120° C.

3. The formulation of claim 1, wherein said at least one plasticizer agent is selected from the following group: NMP, DMSO, diglyme, xylene, dimethyl acetamide, dimethyl formamide, biphenyl, bibenzyl, and diphenyl ether.

4. The formulation of claim 1, wherein said casting solvent is selected from the following group: propylene glycol monomethyl ether acetate (PGMEA), propylene glycol monomethyl ether (PGME), toluene, and diglyme.

5. The formulation of claim 1, wherein said block copolymer material is selected from the following group: poly(styrene-block-methylmethacrylate), poly(styrene-block-dimethylsiloxane) and poly(styrene-block-vinylpyridine).

6. The formulation of claim 1, wherein between 60-90% of said formulation is said casting solvent, between 1-10% of said formulation is said block copolymer material and between 10-40% of said formulation is said at least one plasticizer agent.

7. The formulation of claim 1, wherein about 70% of said formulation is said casting solvent, about 2% of said formulation is said block copolymer material and about 28% of said formulation is said at least one plasticizer agent.

8. The formulation of claim 1, wherein said at least one plasticizer agent and said casting solvent are miscible.

9. A method of forming a DSA-based material layer, comprising:
depositing a liquid DSA formulation on a guide layer, said liquid DSA formulation comprising a block copolymer material, a casting solvent and at least one plasticizing agent;
performing a spin-coating process to form a DSA-based material layer comprised of said liquid DSA formulation above said guide layer, wherein said DSA-based material layer includes said at least one plasticizing agent; and
after performing said spin-coating process, performing at least one heating process on said DSA-based material layer while at least some of said plasticizing agent remains in said DSA-based material layer so as to enable phase separation of said block copolymer materials into a plurality of first and second separated polymer features positioned above said guide layer.

10. The method of claim 9, wherein, during at least a first portion of said spin-coating process, said casting solvent evaporates at a faster rate than does said at least one plasticizer agent.

11. The method of claim 9, wherein, during at least a first portion of said at least one heating process, said casting solvent evaporates at a faster rate than does said at least one plasticizer agent.

12. The method of claim 9, wherein performing said at least one heating process comprises performing a single heating process operation.

13. The method of claim 9, wherein said single heating process operation is performed at a temperature that falls within the range of 150-200° C. for a duration of about three minutes.

14. The method of claim 9, wherein performing said at least one heating process comprises performing a first heating process operation and thereafter performing a second heating process operation.

15. The method of claim 14, wherein said first heating process operation is performed at a lower temperature and for a longer duration than a temperature and duration of said second heating process operation.

16. The method of claim 15, wherein said first heating process operation is performed at a temperature of about 150° C. for a duration of about two minutes and said second heating process operation is performed at a temperature of about 200° C. for a duration of about one minute.

17. The method of claim 9, wherein said at least one heating process is performed for a sufficient duration such that said at least one plasticizer constitutes about 0-5% by mass of said DSA-based material layer after the completion of said at least one heating process.

18. The method of claim 9, further comprising:
performing at least one process operation to remove one of said first and second separated polymer features while leaving the other of said first and second separated polymer features in position above said guide layer so as to thereby form a patterned DSA-based masking layer; and
performing at least one process operation on at least said guide layer through said patterned DSA-based masking layer.

19. The method of claim 9, wherein said first and second separated polymer features positioned above said guide layer are line-type features.

20. The method of claim 9, wherein between 60-90% of said liquid DSA formulation is said casting solvent, between 1-10% of said liquid DSA formulation is said block copolymer material and between 10-40% of said liquid DSA formulation is said at least one plasticizer agent.

21. The method of claim 9, wherein about 70% of said liquid DSA formulation is said casting solvent, about 2% of said liquid DSA formulation is said block copolymer material and about 28% of said liquid DSA formulation is said at least one plasticizer agent.
